(19) United States
(12) Patent Application Publication
(10) Pub. No.: US 2005/0153563 A1
(43) Pub. Date: Jul. 14, 2005

(54) Selective etch of films with high dielectric constant

(75) Inventors: Shyam Ramalingam, Fremont, CA (US); Gowri Kota, Fremont, CA (US); Chris Lee, Oakland, CA (US)

Correspondence Address: BEYER WEAVER & THOMAS LLP, P.O. BOX 70250, OAKLAND, CA, 94612-0250, US

(73) Assignee: Lam Research Corporation

(21) Appl. No.: 10/758,637

(22) Filed: Jan. 14, 2004

(51) Int. Cl. H01L 21/302; H01L 21/461

(52) U.S. Cl. 438/706

(57) ABSTRACT

A method for selectively etching a high dielectric constant layer over a silicon substrate is provided. The silicon substrate is placed into an etch chamber. An etchant gas is provided into the etch chamber, where the etchant gas comprises BCl₃, an inert diluent, and Cl₂, where the flow ratio of the inert diluent to BCl₃ is between 2:1 and 1:2, and where the flow ratio of BCl₃ to Cl₂ is between 2:1 and 20:1. A plasma is generated from the etchant gas to selectively etch the high dielectric constant layer.

### BACKGROUND OF THE INVENTION

1. Field of the Invention

The invention relates to semiconductor devices. More specifically, the invention relates to semiconductor devices with a layer of a high dielectric constant material.

2. Description of the Related Art

Over the past few decades progress in silicon technology has been attained through continual scaling of semiconductor devices to ever-smaller dimensions, resulting in a constant increase in the number of components per chip. The reduction in dimensions has been accompanied by increased performance and decreased cost of devices. Scaling of gate devices, such as a metal-oxide semiconductor field effect transistors (MOSFET), has been primarily enabled by scaling of gate oxide thicknesses, source/drain extension, junction depths, and gate lengths.

At the heart of MOS transistors SiO₂ has been typically used to electrically isolate the transistor gate from the silicon channel. Such a gate oxide may be thermally grown amorphous SiO₂. SiO₂ has been used since it has good insulator properties, low defect densities, and thermal stability. The dielectric constant of SiO₂ is 3.9. The continuous scaling of semiconductor devices already requires limiting the thickness of the SiO₂ gate dielectric film to less than 20 Å for sub-0.13 μm CMOS.

SiO₂ gates that are too thin are be subject to leakage currents arising from electron tunneling through the dielectrics, creating a problem that may be viewed as a technical barrier. In addition, a thin oxide is susceptible to boron penetration from p⁺ doped poly-silicon gate electrodes.

It is desirable to provide small semiconductor devices that are not subject to current leakage and boron penetration.

### SUMMARY OF THE INVENTION

To achieve the foregoing and in accordance with the purpose of the present invention, a method for selectively etching a high dielectric constant layer over a silicon substrate is provided. The silicon substrate is placed into an etch chamber. An etchant gas is provided into the etch chamber, where the etchant gas comprises BCl₃, an inert diluent, and Cl₂, where the flow ratio of the inert diluent to BCl₃ is between 2:1 and 1:2, and where the flow ratio of BCl₃ to Cl₂ is between 2:1 and 20:1. A plasma is generated from the etchant gas to selectively etch the high dielectric constant layer.

In another manifestation of the invention a method for forming a semiconductor device is provided. A high dielectric constant layer is formed over a substrate. A poly-silicon layer is formed over the high dielectric constant layer. A patterned mask is formed over the poly-silicon layer. A feature is etched into the poly-silicon layer through the patterned mask. The high dielectric constant layer is etched to expose the substrate not under the patterned mask, which comprises providing an etchant gas, wherein the etchant gas comprises BCl₃, an inert diluent, and Cl₂, where the flow ratio of the inert diluent to BCl₃ is between 2:1 and 1:2, and where the flow ratio of BCl₃ to Cl₂ is between 2:1 and 20:1 and generating a plasma from the etchant gas to selectively etch the high dielectric constant layer. An ion implantation into the exposed substrate is performed.

These and other features of the present invention will be described in more details below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a schematic view of a field effect transistor that may be formed using an embodiment of the invention.

FIG. 2 is a flow chart of a process used in an embodiment of the invention.

FIGS. 3A-3D are schematic cross-sectional views of a high dielectric constant layer formed according to the invention.

FIG. 4 is a schematic view of a process chamber that may be used in a preferred embodiment of the invention.

FIGS. 5A and 5B illustrate a computer system, which is suitable for implementing a controller.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

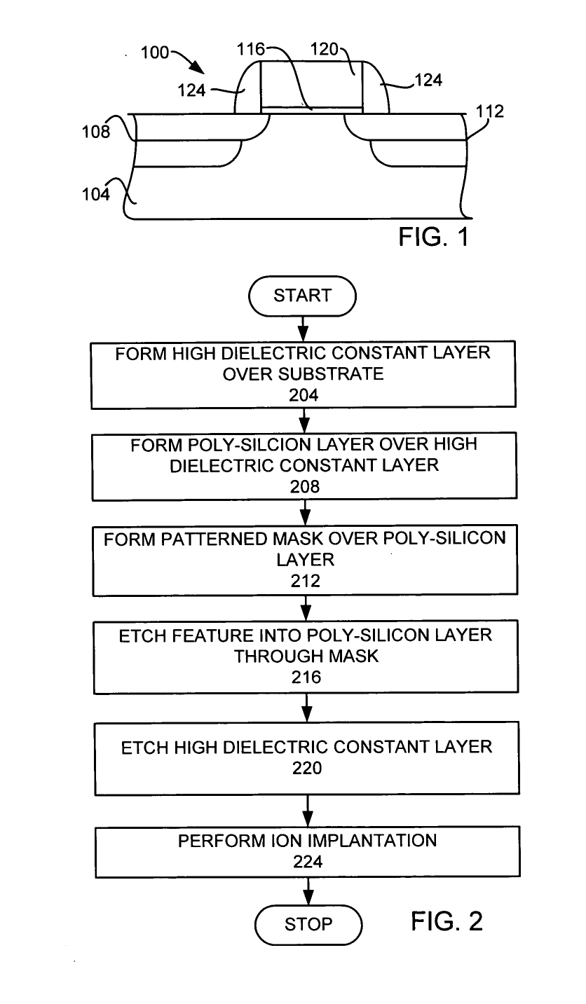

To facilitate understanding. FIG. 1 is a schematic view of a field effect transistor 100. The field effect transistor 100 comprises a substrate 104 into which a source 108 and a drain 112 are doped. A gate oxide 116 is formed over the substrate. A gate electrode 120 is formed over the gate oxide 116, so that the gate oxide 116 forms an insulator between the gate electrode 120 and the channel in the substrate 104 below the gate oxide 116. Spacers 124 are place at ends of the gate electrode 120 and the gate oxide 116. The invention provides a selective etch that allows the gate oxide 116 to be formed from a high dielectric constant material.

In the specification and claims, a high dielectric constant material has a dielectric constant of at least 8 (K≧8).

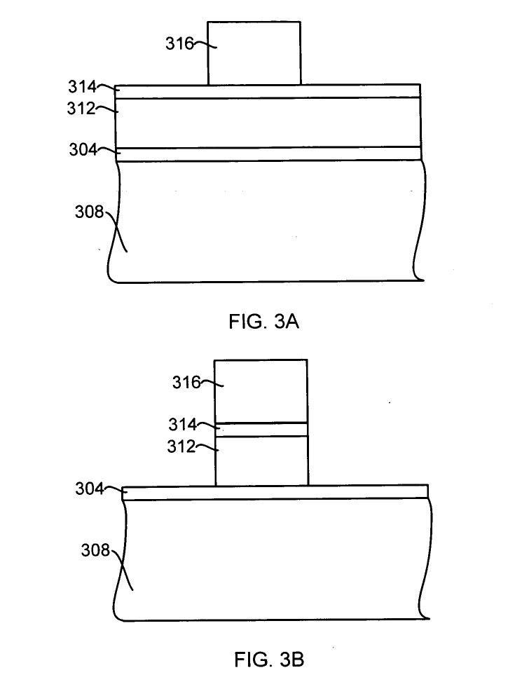

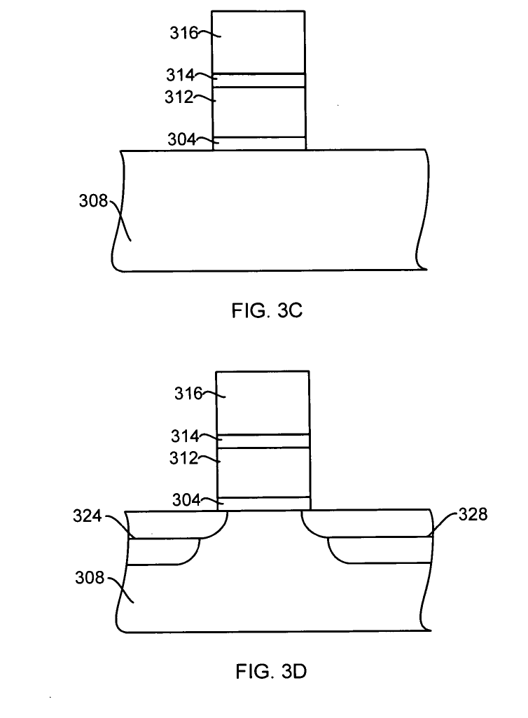

FIG. 2 is a high level flow chart for forming a semiconductor device with a high dielectric constant layer. A layer of high dielectric constant (high K) material is deposited over a substrate (step 204). Atomic layer deposition, sputtering or chemical vapor deposition may be used to deposit the layer of high dielectric constant material. FIG. 3A is a schematic cross-sectional view of a high dielectric constant layer 304 that has been deposited over a substrate 308. The silicon substrate may be substantially crystalline silicon, which may be part of a silicon wafer, or if the semiconductor device is several layers above the wafer, the silicon substrate may be a silicon oxide layer.

A poly-silicon layer 312 is then formed over the high K layer 304 (step 208). A patterned mask 316, such as a photoresist mask is placed over the poly-silicon layer 312 (step 212). An antireflective coating 314 may be between the patterned mask 316 and the poly-silicon layer 312, to facilitate the formation of the patterned mask 316. The poly-silicon layer 312 is then etched through the mask (step 216). FIG. 3B is a schematic cross-sectional view after the poly-silicon layer 312 has been etched.

The high K layer 304 is then etched (step 220), as shown in FIG. 3C. It is desirable that the etch of the high dielectric constant layer 304 be highly selective so as to minimize the etching the underlying substrate 308 and minimize the etching of the poly-silicon layer 312. In the preferred embodiment, the etch is so highly selective that less than 5 Å of the substrate is removed during the etching of the high dielectric constant layer 304.

An ion implantation is performed (step 224) to create the source and drain regions. FIG. 3D is a schematic view after the source regions 324 and drain regions 328 have been formed. Since ion implantation is highly dependent on the characteristics of the substrate, to provide uniform source and drain regions across a wafer, the etching of the substrate must be minimized.

U.S. Pat. No. 6,511,872, by Donnelly, Jr. et al., issued Jan. 28, 2003 discloses a method of etching a high dielectric constant layer over a substrate. An etch chemistry of BCl₃ and Cl₂ is disclosed. However, a process with a high etch selectivity of the high K dielectric layer to substrate is not disclosed. The article “Etching of high-k dielectric Zr₁₋ₓAlₓO_{y} films in chlorine-containing plasmas” by K. Pelhos et al., published in the Journal of Vacuum Science Technology A 19(4) July/August 2001 pp. 1361-1366 discusses the same etch chemistry and also does not disclose a process with a high etch selectivity.

The article “Plasma Etching Selectivity of ZrO₂ to Si in BCl₃/Cl₂ Plasmas,” by Lin Sha and Jane P. Chang, in the Journal of Vacuum Science Technology A 21(6) July/August 2001 pp. 1915-1922 discloses a method of etching a high dielectric constant layer over a substrate. An etchant chemistry of BCl₃, Cl₂ and 5% Ar are disclosed. This article states that the highest etch selectivity of 1.5 was reached by using pure BCl₃. It is desirable to have higher etch selectivities to minimize the etching of the substrate.

In a preferred embodiment of the invention, the high dielectric constant layer may be formed from a material with a dielectric constant of at least 8, such as Hf silicate (K≅11), HfO₂ (K≅25-30), Zr silicate (K≅11-13), ZrO₂ (K≅22-28), Al₂O₃ (K≅8-12)), La₂O₃ (K≅25-30), SrTiO₃ (K≅200), SrZrO₃ (K≅25), TiO₂ (K≅80), and Y₂O₃ (K≅8-15).

More Detailed Description of the High K Dielectric Etch

In a more detailed description of the high K dielectric etch, during the high K layer 304 etch (step 220), the wafer is placed in an etch chamber. The etch chamber may be used for etching the poly-silicon layer (step 216) or a different chamber may be used to for etching the poly-silicon layer.

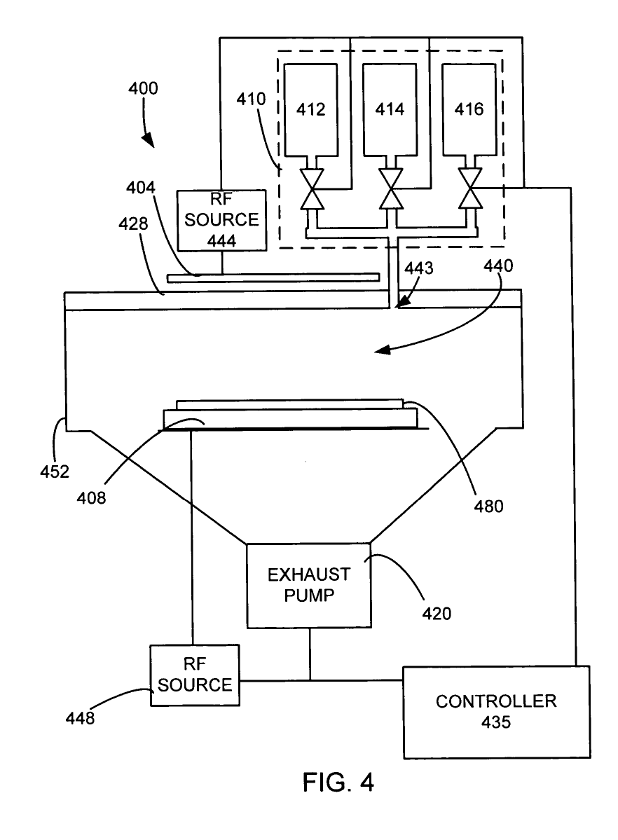

FIG. 4 is a schematic view of a process chamber 400 that may be used in the preferred embodiment of the invention. In this embodiment, the plasma processing chamber 400 comprises an inductive coil 404, a lower electrode 408, a gas source 410, and an exhaust pump 420. Within plasma processing chamber 400, the substrate 308 is positioned upon the lower electrode 408. The lower electrode 408 incorporates a suitable substrate chucking mechanism (e.g., electrostatic, mechanical clamping, or the like) for supporting the substrate 308. The reactor top 428 incorporates a dielectric window. The chamber top 428, chamber walls 452, and lower electrode 408 define a confined plasma volume 440. Gas is supplied to the confined plasma volume by gas source 410 through a gas inlet 443 and is exhausted from the confined plasma volume by the exhaust pump 420. The exhaust pump 420 forms a gas outlet for the plasma processing chamber. A first RF source 444 is electrically connected to the coil 404. A second RF source 448 is electrically connected to the lower electrode 408. In this embodiment, the first and second RF sources 444, 448 comprise a 13.56 MHz power source. Different combinations of connecting RF power to the electrodes are possible. A controller 435 is controllably connected to the first RF source 444, the second RF source 448, the exhaust pump 420, and the gas source 410.

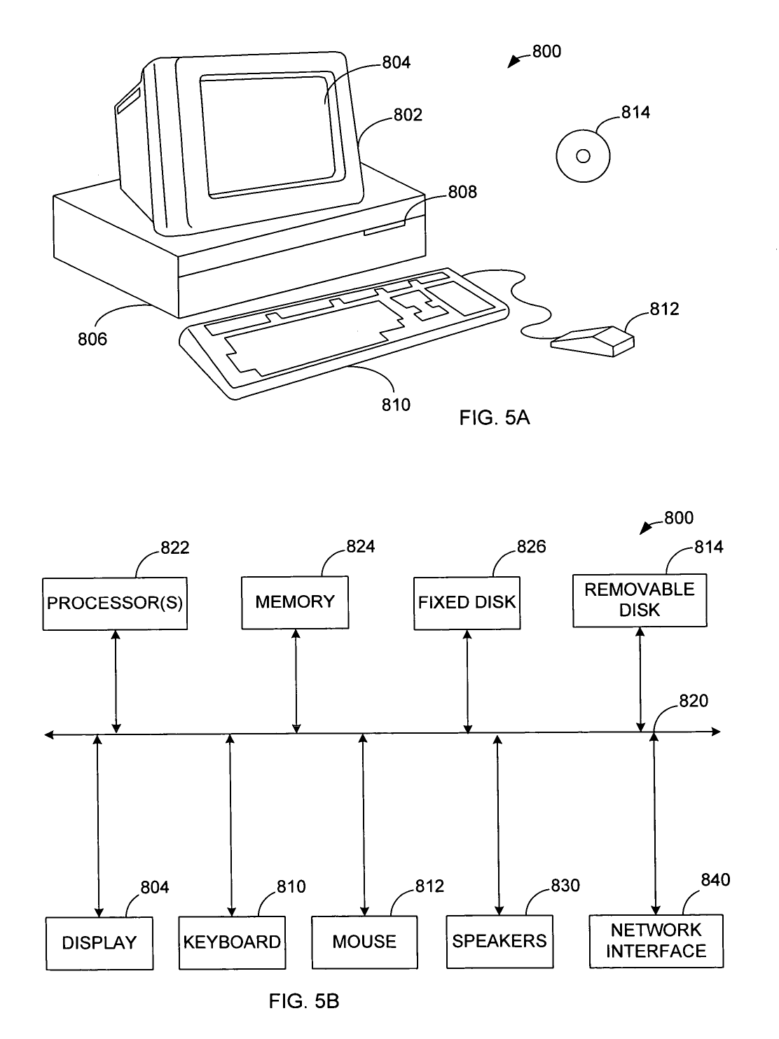

FIGS. 5A and 5B illustrate a computer system 800, which is suitable for implementing a controller 435 used in embodiments of the present invention. FIG. 5A shows one possible physical form of the computer system. Of course, the computer system may have many physical forms ranging from an integrated circuit, a printed circuit board, and a small handheld device up to a huge super computer. Computer system 800 includes a monitor 802, a display 804, a housing 806, a disk drive 808, a keyboard 810, and a mouse 812. Disk 814 is a computer-readable medium used to transfer data to and from computer system 800.

FIG. 5B is an example of a block diagram for computer system 800. Attached to system bus 820 is a wide variety of subsystems. Processor(s) 822 (also referred to as central processing units or CPUs) are coupled to storage devices, including memory 824. Memory 824 includes random access memory (RAM) and read-only memory (ROM). As is well known in the art, ROM acts to transfer data and instructions uni-directionally to the CPU and RAM is used typically to transfer data and instructions in a bi-directional manner. Both of these types of memories may include any suitable of the computer-readable media described below. A fixed disk 826 is also coupled bi-directionally to CPU 822; it provides additional data storage capacity and may also include any of the computer-readable media described below. Fixed disk 826 may be used to store programs, data, and the like and is typically a secondary storage medium (such as a hard disk) that is slower than primary storage. It will be appreciated that the information retained within fixed disk 826 may, in appropriate cases, be incorporated in standard fashion as virtual memory in memory 824. Removable disk 814 may take the form of any of the computer-readable media described below.

CPU 822 is also coupled to a variety of input/output devices, such as display 804, keyboard 810, mouse 812 and speakers 830. In general, an input/output device may be any of: video displays, track balls, mice, keyboards, microphones, touch-sensitive displays, transducer card readers, magnetic or paper tape readers, tablets, styluses, voice or handwriting recognizers, biometrics readers, or other computers. CPU 822 optionally may be coupled to another computer or telecommunications network using network interface 840. With such a network interface, it is contemplated that the CPU might receive information from the network, or might output information to the network in the course of performing the above-described method steps. Furthermore, method embodiments of the present invention may execute solely upon CPU 822 or may execute over a network such as the Internet in conjunction with a remote CPU that shares a portion of the processing.

In addition, embodiments of the present invention further relate to computer storage products with a computer-readable medium that have computer code thereon for performing various computer-implemented operations. The media and computer code may be those specially designed and constructed for the purposes of the present invention, or they may be of the kind well known and available to those having skill in the computer software arts. Examples of computer-readable media include, but are not limited to: magnetic media such as hard disks, floppy disks, and magnetic tape; optical media such as CD-ROMs and holographic devices; magneto-optical media such as floptical disks; and hardware devices that are specially configured to store and execute program code, such as application-specific integrated circuits (ASICs), programmable logic devices (PLDs) and ROM and RAM devices. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

An etchant gas of BCl₃, and inert diluent, and Cl₂ is provided from the gas source 410 to the area of the plasma volume. The inert diluent may be any inert gas such as neon, argon, or xenon. More preferably, the inert diluent is argon. Therefore, the gas source 410 may comprise a BCl₃ source, a Cl₂ source 414, and an argon source 416. The controller 435 is able to control the flow rate of the various gases.

The gas source 410 provides flow rates of BCl₃ and argon so that the flow ratio of argon to BCl₃ is between 2:1 and 1:2. More preferably, the ratio of flow rates of BCl₃ and argon is between 3:2 and 2:3. Most preferably, the ratio of the flow rates of BCl₃ and argon is about 1:1. In addition, the gas source provides flow rates of BCl₃ and Cl₂ so that the flow ratio of BCl₃ to Cl₂ is between 2:1 and 20:1. More preferably, the ratio of flow rates of BCl₃ to Cl₂ is between 8:1 and 16:1. Preferably, the flow of chlorine is between 25 and 100 sccm.

During the etch, the wafer is maintained at a temperature below 150° C. More preferably, the wafer temperature is maintained at a temperature below 100° C. Most preferably, the wafer temperature is maintained at a temperature below 70° C. Although other methods may require a high temperature, which requires heating, to provide a selective etch, the invention may be performed without heating the wafer, which prevents thermal damage to the wafer. In addition, the lower temperatures create less problems than methods that require that the wafer is heated.

The controller 435 controls the exhaust pump 448 and gas source 410 to control the chamber pressure. Preferably, the chamber pressure is no greater than 40 mTorr during the etch of the high dielectric constant layer. More preferably, the chamber pressure is no greater than 20 mTorr during the etch.

A D.C. bias may be applied to the lower electrode. Preferably, the absolute value of the D.C. bias is less than 15 volts. More preferably, the absolute value of the D.C. bias is less than 5 volts. Most preferably, no D.C. bias is applied to the lower electrode. Preferably, the upper RF source provides greater than 600 Watts (TCP) through the coil 404 to the etch chamber at a frequency of about 13.56 MHz. More preferably, the upper RF source provides at least 700 Watts (TCP) through the coil 404 to the etch chamber at a frequency of about 13.56 MHz.

Since there is very little bias, the inert diluent is not used for bombardment. An unexpected result of having the recited ratio of inert diluent to BCl₃ is that both etch selectivity is improved and the etch rate is improved. Without wishing to be bound by theory, it is believed that this result is caused by an increase the electron temperature caused by the cited ratio of inert diluent to BCl₃. It is believed that higher argon flows would result in a more depositing chemistry and lower argon flows would result in less depositing and lower selectivity.

The recited ratio of BCl₃ to inert diluent provides a desired control of the electron temperature. BCl₃ causes deposition on the wafer. The recited ratio of BCl₃ to Cl₂ allows sufficient Cl₂ to clean up deposits from the BCl₃, which prevents the formation of footers in a tapered etch, without significantly sacrificing selectivity.

Without wishing to be bound by theory, it is also believed that the use of a lower chamber pressure and high TCP cause high dissociation of BCl₃ and BCl₂⁺. It is further believed that the more further dissociated species provides the desired etching.

The inventive high dielectric constant layer etch is able to provide an etch selectivity with respect to silicon of greater than 4:1. More preferably, the inventive high dielectric constant layer etch is able to provide an etch selectivity of greater than 10:1. Most preferably, the inventive high dielectric constant layer etch is able to provide an etch selectivity wit respect to crystalline silicon of about infinity. The inventive high dielectric constant layer etch is also able to provide an etch selectivity with respect to silicon oxide of greater than 5:1.

Preferably, the inventive high constant layer etch is able to provide and etch rate of between 50-150 Å/minute. More preferably, the inventive high constant layer etch is able to provide and etch rate of between 70-90 Å/minute. If the etch rate is too slow, the process time in undesirably increased. If the etch rate is too fast, it is difficult to control the etching.

The invention also unexpectedly provides good etch uniformity.

### EXAMPLE

In this example, a Versys 2300 built by Lam Research Corporation of Fremont Calif. is used for etching the high K layer. Both the bottom and top RF sources provide a power signal at a frequency of 13.56 MHz. The chamber pressure was set to 20 mTorr. The RF sources provide 1100 Watts TCP (Transformer Coupled Power). No DC bias power is applied to the wafer. The wafer is maintained at a temperature of about 70° C. An etchant gas is flowed into the etch chamber where the etchant gas consists essentially of 400 sccm BCl₃, 50 sccm Cl₂, and 380 sccm Ar.

A spectroscopic ellipsometer was used to measure the pre-etch blanket film thickness and the post-etch blanket film thickness after 1 minute of etching a 200 mm diameter wafer with 6 mm edge exclusion. The difference between the pre-etch blanket film thickness and the post-etch blanket film thickness was measured for 49 points distributed around the wafer. In this example, the selective etching of the high K dielectric with respect to the crystalline silicon provides an etch selectivity of about infinity with a resulting etch rate of about 70-90 Å/minute. The mean etch rate was found to be 83 Å/minute. The range of measured etch rates varied by about 6Å/minute. The 3 standard deviations were calculated as being 5 Å/minute. It was found that less than 6% of the data was outside of 3 standard deviations.

While this invention has been described in terms of several preferred embodiments, there are alterations, permutations, modifications and various substitute equivalents, which fall within the scope of this invention. It should also be noted that there are many alternative ways of implementing the methods and apparatuses of the present invention. It is therefore intended that the following appended claims be interpreted as including all such alterations, permutations, modifications, and various substitute equivalents as fall within the true spirit and scope of the present invention.

1. A method for selectively etching a high dielectric constant layer over a silicon substrate, comprising:
placing the silicon substrate into an etch chamber;
providing an etchant gas into the etch chamber, wherein the etchant gas comprises BCl₃, an inert diluent, and Cl₂, wherein the flow ratio of the inert diluent to BCl₃ is between 2:1 and 1:2, and wherein the flow ratio of BCl₃ to Cl₂ is between 2:1 and 20:1; and
generating a plasma from the etchant gas to selectively etch the high dielectric constant layer.

2. The method, as recited in claim 1, further comprising maintaining the wafer temperature below 150° C. during the etching.

3. The method, as recited in claim 2, further comprising providing a DC bias of less than 5 volts.

4. The method, as recited in claim 3, further comprising maintaining a pressure within the chamber to less than 40 mTorr during the etch.

5. The method, as recited in claim 4, wherein the generating a plasma comprises providing more than 700 Watts of Transformer Coupled Power into the etch chamber to energize the etchant gas.

6. The method, as recited in claim 5, wherein the inert diluent is argon.

7. The method, as recited in claim 6, wherein the etchant gas consists essentially of BCl₃, argon, and Cl₂.

8. The method, as recited in claim 7, wherein the selectivity for etching the high dielectric constant layer with respect to silicon is greater than 4:1.

9. The method, as recited in claim 8, where the etch rate of the high dielectric constant layer is between 50-150 Å/minute.

10. The method, as recited in claim 9, wherein the high dielectric constant layer has a dielectric constant of at least 8.

11. The method, as recited in claim 1, further comprising providing a DC bias with an absolute value of less than 5 volts.

12. The method, as recited in claim 1, further comprising maintaining a pressure within the chamber to less than 40 mTorr during the etch.

13. The method, as recited in claim 1, wherein the inert diluent is argon.

14. The method, as recited in claim 1, wherein the etchant gas consists essentially of BCl₃, argon, and Cl₂.

15. The method, as recited in claim 1, wherein the selectivity for etching the high dielectric constant layer with respect to silicon is greater than 4:1.

16. The method, as recited in claim 1, where the etch rate of the high dielectric constant layer is between 50-150 Å/minute.

17. The method, as recited in claim 1, wherein the high dielectric constant layer has a dielectric constant at least 8.

18. A method for forming a semiconductor device, comprising:
forming a high dielectric constant layer over a substrate;
forming a poly-silicon layer over the high dielectric constant layer;
forming a patterned mask over the poly-silicon layer;
etching a feature into the poly-silicon layer through the patterned mask;
etching the high dielectric constant layer to expose the substrate not under the patterned mask, comprising the steps of:
providing an etchant gas, wherein the etchant gas comprises BCl₃, an inert diluent, and Cl₂, wherein the flow ratio of the inert diluent to BCl₃ is between 2:1 and 1:2, and wherein the flow ratio of BCl₃ to Cl₂ is between 2:1 and 20:1; and
generating a plasma from the etchant gas to selectively etch the high dielectric constant layer; and
performing an ion implantation into the exposed substrate.

19. The method, as recited in claim 18, further comprising maintaining the wafer temperature below 150° C. during the etching.

20. The method, as recited in claim 18, further comprising providing a DC bias with an absolute value of less than 5 volts.
